(19) United States
(12) Patent Application Publication
(10) Pub. No.: US 2015/0166402 A1
(43) Pub. Date: Jun. 18, 2015

(54) GLASS

(71) Applicant: Nippon Electric Glass Co., Ltd., Shiga (JP)

(72) Inventors: Masato Muguruma, Shiga (JP); Hironori Takase, Shiga (JP); Shinkichi Miwa, Shiga (JP)

(73) Assignee: Nippon Electric Glass Co., Ltd., Shiga (JP)

(21) Appl. No.: 14/371,485

(22) PCT Filed: Jan. 11, 2013
(86) PCT No.: PCT/JP2013/050363

§ 371 Date: Jul. 10, 2014

(30) Foreign Application Priority Data
Jan. 12, 2012 (JP) 2012-004158

(51) Int. Cl. C03C 3/087; H01L 31/048

(52) U.S. Cl. CPC C03C 3/087; H01L 31/0481

(57) ABSTRACT

Provided is a glass, including, as a glass composition, in mass % in terms of the following oxides, 40 to 65% of SiO₂, 2 to 20% of Al₂O₃, 0 to 20% of B₂O₃, 0 to 15% of MgO, 0 to 15% of CaO, 0 to 20% of SrO, 0 to 20% of BaO, 0 to 10% of Li₂O, 0.1 to 20% of Na₂O, 0.1 to 20% of K₂O, 0 to 10% of ZrO₂, 0 to less than 0.04% of Fe₂O₃, and 0 to 0.5% of SO₃, in which a transmittance of the glass with a thickness of 1.8 mm at a wavelength 1,100 nm is 86 to 92%.

### TECHNICAL FIELD

The present invention relates to glass, in particular, glass suitable for a flat panel display (FPD) such as a plasma display panel (PDP), a thin-film solar cell such as a CIS-based solar cell or a CdTe-based solar cell, and a dye-sensitized solar cell.

### BACKGROUND ART

A PDP is manufactured as described below. First, a transparent electrode such as an ITO film or an NESA film is formed on a surface of a front glass sheet, a dielectric layer is formed thereon, an electrode made of, for example, Al, Ag, or Ni is formed on a surface of a back glass sheet, a dielectric layer is formed thereon, and in addition, a dividing wall is formed thereon. Next, the front glass sheet and the back glass sheet are opposed to each other to position the electrodes and the like, and then the outer peripheral edge portions of the front glass sheet and back glass sheet are subjected to frit sealing in the temperature region of 450 to 550° C. After that, the air inside the resultant panel is evacuated to create a vacuum through an exhaust pipe and a noble gas is introduced into the panel, followed by sealing.

Hitherto, a glass sheet comprising soda-lime glass (having a thermal expansion coefficient of about 84×10⁻⁷/° C.) formed so as to have a thickness of 1.5 to 3.0 mm by a float method or the like has been used in a PDP. However, soda-lime glass has a strain point of about 500° C., and hence is liable to have thermal deformation and thermal shrinkage in a heat treatment step. Thus, a glass sheet having a thermal expansion coefficient comparable to that of soda-lime glass and having a higher strain point is used at present.

Meanwhile, in a thin-film solar cell such as a CIS-based solar cell, Cu(InGa)Se₂, which is a chalcopyrite-type compound semiconductor comprising Cu, In, Ga, and Se, is formed as a photoelectric conversion film on a glass sheet. In order to coat a glass sheet with Cu, In, Ga, and Se by a multi-source deposition method, a selenization method, or the like to form a chalcopyrite-type compound, a heat treatment step at about 500 to 600° C. is required. Further, a large difference in thermal expansion coefficient between the photoelectric conversion film and the glass sheet results in a film peeling defect, and hence the conversion efficiency thereof is liable to deteriorate. Thus, the thermal expansion coefficient of the glass sheet needs to be restricted within a proper range.

In a CdTe-based solar cell as well, a photoelectric conversion film comprising Cd and Te is formed on a glass substrate. Also in this case, a heat treatment step at about 500° C. to 600° C. is required to form a TCO film and a CdTe film. Further, a large difference in thermal expansion coefficient between the photoelectric conversion film and the glass sheet results in a film peeling defect, and hence the conversion efficiency thereof is liable to deteriorate. Thus, the thermal expansion coefficient of the glass sheet needs to be restricted within a proper range.

Hitherto, a soda-lime glass sheet has been used as a glass sheet in the CIS-based solar cell, the CdTe-based solar cell, or the like. However, soda-lime glass is liable to have thermal deformation and thermal shrinkage in a heat treatment step at high temperature. In order to solve this problem, the use of a high strain point glass sheet as a glass sheet has been currently studied (see Patent Literature 4).

### CITATION LIST

### Patent Literature

Patent Literature 1: JP 2006-252828 A
Patent Literature 2: JP 10-72235 A
Patent Literature 3: JP 2000-143284 A
Patent Literature 4: JP 11-135819 A

### SUMMARY OF INVENTION

### Technical Problem

By the way, in order to reduce the power consumption of an FPD such as a PDP, it is effective to reduce the content of a colorant such as iron, thereby increasing the transmittance of a glass sheet. However, high strain point glass conventionally used in a PDP contains much iron to adjust the color tone thereof, and hence the transmittance of the high strain point glass is not sufficiently high in the range of from the visible long-wavelength region to the near-infrared region. For example, it is disclosed in Patent Literatures 1 and 2 that conventional high strain point glass contains much iron.

Further, it is feared that in a CIS-based solar cell, iron in a glass sheet diffuses in a photoelectric conversion layer, resulting in the deterioration of the conversion efficiency thereof. Moreover, it is believed that, when a glass sheet containing much iron is used in a CdTe-based solar cell and a dye-sensitized solar cell, the iron absorbs much light, with the result that the amount of light arriving at a photoelectric conversion layer reduces, resulting in the deterioration of the conversion efficiency thereof.

Further, Patent Literatures 1 and 2 each disclose glass having a high strain point and having a low iron content. However, this glass contains relatively much iron for the purpose of adjusting the contrast, and hence has not been able to solve the above-mentioned problem perfectly.

Besides, it is important to match the thermal expansion coefficient of a glass sheet with those of peripheral members (such as a seal frit and a photoelectric conversion film), from the viewpoint of avoiding a seal defect of a display such as a PDP and the deterioration of the conversion efficiency of a solar cell.

In addition, it is important to increase the strain point of a glass sheet, from the viewpoint of avoiding a pattern shift due to the dimensional change thereof, the bending thereof, and the like in a heat treatment step at high temperature such as a sealing step for a PDP and a film-forming step for a solar cell. In particular, it is believed that, when a photoelectric conversion film formed at high temperature is used in a CIS-based solar cell, the conversion efficiency thereof increases, and when a photoelectric conversion film formed at high temperature is used in a CdTe solar cell, the production efficiency thereof increases.

However, glass having a high strain point and a thermal expansion coefficient matched with those of peripheral members is liable to have a high iron content or a high refractive index, and hence is liable to have a low transmittance. The glass sheet disclosed in Patent Literature 1 has a glass composition designed in consideration of a thermal expansion coefficient and a strain point. However, the glass sheet has an Fe₂O₃ content of 600 to 2,000 ppm, and hence has the problem of having a low transmittance owing to the light absorption of Fe²⁺ having a peak at a wavelength of about 1,000 to 1,200 nm. When this glass sheet is used in a display, the light absorption of the glass sheet causes the reduction of the luminance of the display, resulting in an increase in power consumption. Meanwhile, it is feared that, when this glass sheet is used in a solar cell, the amount of light arriving at a photoelectric conversion layer reduces or iron in the glass sheet diffuses in a photoelectric conversion layer, resulting in the deterioration of the conversion efficiency thereof.

Further, the glass sheet disclosed in Patent Literature 2 has a glass composition designed in consideration of a strain point, a thermal expansion coefficient, and a transmittance. However, the iron content of this glass sheet is 400 ppm or more, and hence the glass sheet cannot contribute to solving the problem that the transmittance of a glass sheet decreases in the range of from the visible long-wavelength region to the near-infrared region owing to the light absorption of Fe²⁺ having a peak at a wavelength of about 1,000 to 1,200 nm.

In addition, patent Literature 3 discloses a glass sheet having a high transmittance. This glass sheet has a thermal expansion coefficient of about 84×10⁻⁷/° C. but has a strain point of about 510° C. Thus, when the glass sheet is used in a display, problems such as a pattern shift due to the dimensional change thereof and thermal deformation are caused. Meanwhile, when the glass sheet is used in a solar cell, a process for forming a photoelectric conversion film cannot be carried out at high temperature, resulting in the formation of a film at a slow rate, and hence problems such as the deterioration of conversion efficiency or production efficiency are caused.

Thus, a technical object of the present invention is to invent glass (in particular, a glass sheet) having a high transmittance, a high strain point, and a proper thermal expansion coefficient.

### Solution to Problem

The inventors of the present invention have made intensive studies and have consequently found that the above-mentioned technical object can be achieved by restricting the composition of glass within a predetermined range and strictly restricting the transmittance of the glass. Thus, the finding is proposed as the present invention. That is, a glass of the present invention comprises, as a glass composition, in mass % in terms of the following oxides, 40 to 65% of SiO₂, 2 to 20% of Al₂O₃, 0 to 20% of B₂O₃, 0 to 15% of MgO, 0 to 15% of CaO, 0 to 20% of SrO, 0 to 20% of BaO, 0 to 10% of Li₂O, 0.1 to 20% of Na₂O, 0.1 to 20% of K₂O, 0 to 10% of ZrO₂, 0 to less than 0.04% of Fe₂O₃, and 0 to 0.5% of SO₃, in which a transmittance of the glass with a thickness of 1.8 mm at a wavelength 1,100 nm is 86 to 92%. Herein, the “transmittance of a glass with a thickness of 1.8 mm at a wavelength 1,100 nm” refers to a transmittance measured with a general-purpose visible-infrared spectrophotometer at 25° C. in the air by using, as a sample, a glass whose both surfaces have been subjected to mirror polishing so as to have a sheet shape, the measurement being performed in a state in which a transparent conductive film, an anti-reflective film, and the like are not formed on the glass. Note that, when the thickness of the sample is less than 1.8 mm, it is possible to convert the thickness of the sample to 1.8 mm by using Mathematical Expression 1 and perform measurement. The refractive index n₁₁₀₀ at a wavelength of 1,100 nm is a value calculated on the basis of the Cauchy's dispersion formula by using refractive indices at wavelengths of 587.6 nm, 780 nm, 1,310 nm, and 1,550 nm.

T_{1.8 mm}=(1−R)²×exp[(t/L)×ln {( 1/100)/(1−R)²}]×100 (Mathematical Expression 1)

where
R={(nx−1)/(nx+1)}²
L: Thickness of a sample (mm)
t: Converted thickness (1.8 mm or 3.2 mm)
T: Transmittance of a sample with a thickness of L at a wavelength of 1,100 nm (%)
nx: Refractive index at a wavelength of x, where x=1,100 nm and 587.6 nm

The glass of the present invention has the glass composition ranges restricted as mentioned above. As a result, the glass is likely to have a strain point of 520 to 700° C. and a thermal expansion coefficient of 70×10⁻⁷ to 100×10⁻⁷/° C.

Further, the transmittance of the glass sheet of the present invention with a thickness of 1.8 mm at a wavelength 1,100 nm is 86 to 92%. With this, the problem that the transmittance of a glass sheet decreases in the range of from the visible long-wavelength region to the near-infrared region can be solved.

Second, in the glass of the present invention, it is preferred that the mass ratio of Fe²⁺ in terms of FeO with respect to a total iron content (t-Fe) in terms of Fe₂O₃, that is, Fe²⁺/t-Fe be 0.70 or less. Herein, “the mass ratio of Fe²⁺ in terms of FeO with respect to a total iron content (t-Fe) in terms of Fe₂O₃, that is, Fe²⁺/t-Fe” can be measured through chemical analysis. Note that “total iron content (t-Fe)” is expressed in terms of “Fe₂O₃” regardless of the valence of Fe.

Third, the glass of the present invention preferably comprises, in mass % in terms of the following oxides, 0.005 to 0.1% of SO₃ and 0.001 to 0.035% of Fe₂O₃.

Fourth, the glass of the present invention preferably has a strain point of 520 to 700° C. Herein, the “strain point” refers to a value measured on the basis of ASTM C336-71.

Fifth, the glass of the present invention preferably has a thermal expansion coefficient at 30 to 380° C. of 70×10⁻⁷ to 100×10⁻⁷/° C. Herein, the “thermal expansion coefficient” refers to a value of an average thermal expansion coefficient at 30 to 380° C. measured with a dilatometer.

Sixth, the glass of the present invention preferably has a sheet shape and has at least one of an anti-reflective film and a transparent conductive film formed on a surface thereof.

Seventh, the glass of the present invention is preferably used in a display.

Eighth, the glass of the present invention is preferably used in a solar cell.

### BRIEF DESCRIPTION OF DRAWINGS

FIG. 1 shows data on a relationship between the transmittance of a glass with a thickness of 1.8 mm at a wavelength 1,100 nm and the residual SO₃ amount in the glass.

FIG. 2 shows data on refractive index dependence of the maximum value of an internal transmittance measured in consideration of reflection at the interface between glass and air.

FIG. 3 is a transmittance curve of Sample No. 1 with a thickness of 1.8 mm at a wavelength of 1,100 nm.

FIG. 4 is a transmittance curve of Sample No. 2 with a thickness of 1.8 mm at a wavelength of 1,100 nm.

FIG. 5 is a transmittance curve of Sample No. 3 with a thickness of 1.8 mm at a wavelength of 1,100 nm.

FIG. 6 is a transmittance curve of Sample No. 5 with a thickness of 1.8 mm at a wavelength of 1,100 nm.

FIG. 7 is a transmittance curve of Sample No. 6 with a thickness of 1.8 mm at a wavelength of 1,100 nm.

FIG. 8 is a transmittance curve of Sample No. 7 with a thickness of 1.8 mm at a wavelength of 1,100 nm.

### DESCRIPTION OF EMBODIMENTS

A glass according to an embodiment of the present invention comprises as a glass composition, in mass % in terms of the following oxides, 40 to 65% of SiO₂, 2 to 20% of Al₂O₃, 0 to 20% of B₂O₃, 0 to 15% of MgO, 0 to 15% of CaO, 0 to 20% of SrO, 0 to 20% of BaO, 0 to 10% of Li₂O, 0.1 to 20% of Na₂O, 0.1 to 20% of K₂O, 0 to 10% of ZrO₂, 0 to less than 0.04% of Fe₂O₃, and 0 to 0.5% of SO₃. The reasons why the content of each component was restricted as described above are shown below.

SiO₂ is a component that forms a network of glass. The content of SiO₂ is 40 to 65%, preferably 42 to 62%, more preferably 45 to 60%, still more preferably 50 to 58%. When the content of SiO₂ is too large, the viscosity at high temperature improperly increases, the meltability and formability are liable to lower, and the thermal expansion coefficient lowers excessively, with the result that it is difficult to match the thermal expansion coefficient with those of peripheral members such as a seal frit. Note that, in the glass composition system according to this embodiment, even if the content of SiO₂ is increased, the strain point does not rise significantly. On the other hand, when the content of SiO₂ is too small, the denitrification resistance and climate resistance are liable to deteriorate. In addition, the thermal expansion coefficient increases excessively, and the thermal shock resistance is liable to lower, with the result that the glass sheet is liable to have a crack in a heat treatment step at the time of producing a PDP or the like.

Al₂O₃ is a component that increases the strain point and is a component that enhances the climate resistance and chemical durability. The content of Al₂O₃ is 2 to 20%, preferably 3 to 17.5%, more preferably 5 to 15%, still more preferably 7.5 to 14%. When the content of Al₂O₃ is too large, the viscosity at high temperature improperly increases, and the meltability and formability are liable to lower. On the other hand, when the content of Al₂O₃ is too small, the strain point is liable to lower.

B₂O₃ is a component that reduces the viscosity of glass, thereby lowering the melting temperature and forming temperature, but is a component that lowers the strain point and a component that causes a furnace refractory material to wear with the volatilization of components at the time of melting. Thus, the content of B₂O₃ is 0 to 15%, preferably 0 to 5%, more preferably 0 to 1%, still more preferably 0 to 0.1%.

MgO is a component that reduces the viscosity at high temperature to increase the meltability and formability. Further, MgO is a component that has a great effect of preventing the glass sheet from being easily broken among alkaline earth metal oxides. On the other hand, MgO is a component that is liable to deteriorate the devitrification resistance. Further, magnesium hydroxide and dolomite, which are materials for introducing MgO, comprises relatively much Fe₂O₃ as an impurity. Thus, in order to satisfy a demand for a high transmittance, the use amount of MgO is restricted. The content of MgO is 0 to 15%, preferably 0.01 to 10%, more preferably 0.03 to 8%, still more preferably 0.05 to 6%.

CaO is a component that reduces the viscosity at high temperature to increase the meltability and formability. The content of CaO is 0 to 15%, preferably 1.5 to 10%, more preferably 4 to 8%. When the content of CaO is too large, the devitrification resistance is liable to deteriorate and a glass sheet is difficult to be formed. On the other hand, when the content of CaO is too small, the viscosity at high temperature improperly increases and the meltability and formability are liable to lower. Further, limestone, calcium carbonate, dolomite, and the like, which are materials for introducing CaO, comprise relatively much Fe₂O₃ as an impurity. Thus, in order to satisfy a demand for a high transmittance, the use amount of CaO is restricted. Besides, CaO is a component that increases the refractive index, and hence has the effect of increasing the reflectance at the interface between glass and air to decrease the transmittance.

SrO is a component that reduces the viscosity at high temperature to increase the meltability and formability. Further, SrO is a component that prevents devitrified crystals of the ZrO₂ system from easily precipitating when SrO coexists with ZrO₂. The content of SrO is 0 to 20%, preferably 2 to 18%, more preferably 3 to 15%, still more preferably 5 to 13%. When the content of SrO is too large, devitrified crystals of the feldspar group are liable to precipitate and the material cost significantly increases. On the other hand, when the content of SrO is too small, the above-mentioned effects are hardly provided. Besides, SrO is a component that increases the refractive index, and hence has the effect of increasing the reflectance at the interface between glass and air to decrease the transmittance. In addition, when the content of SrO is too small, the viscosity at high temperature improperly increases and the meltability and formability are liable to lower.

BaO is a component that reduces the viscosity at high temperature to increase the meltability and formability. The content of BaO is 0 to 20%, preferably more than 2.0 to 15%, more preferably 3 to 10%. When the content of BaO is too large, devitrified crystals of the barium feldspar group are liable to precipitate and the material cost significantly increases. In addition, the density increases and the cost of a supporting member is liable to increase significantly. On the other hand, when the content of BaO is too small, the viscosity at high temperature improperly increases, and the meltability and formability are liable to lower. Besides, BaO is a component that increases the refractive index, and hence has the effect of increasing the reflectance at the interface between glass and air to decrease the transmittance.

Li₂O is a component that adjusts the thermal expansion coefficient and a component that reduces the viscosity at high temperature to increase the meltability and formability. However, Li₂O is a component whose material cost is high and which significantly lowers the strain point. Thus, the content of Li₂O is 0 to 10%, preferably 0 to 2%, more preferably 0 to less than 0.1%.

Na₂O is a component that adjusts the thermal expansion coefficient and a component that reduces the viscosity at high temperature to increase the meltability and formability. Further, when used in a CIS-based solar cell, Na₂O is a useful component that improves the conversion efficiency through the diffusion of Na in glass in the photoelectric conversion film. The content of Na₂O is 0.1 to 20%, preferably 2 to 15%, more preferably 3 to 12%. When the content of Na₂O is too large, the strain point is liable to lower, the thermal expansion coefficient increases excessively, and the thermal shock resistance is liable to lower. As a result, the glass sheet is liable to have thermal shrinkage and thermal deformation, and to have a crack in a heat treatment step at the time of producing a PDP or the like. On the other hand, when the content of Na₂O is too small, the above-mentioned effects are hardly provided.

K₂O is a component that adjusts the thermal expansion coefficient and a component that reduces the viscosity at high temperature to increase the meltability and formability. When the content of K₂O is too large in a glass system comprising Al₂O₃ at more than 10%, devitrified crystals of the KAlSiO system are liable to precipitate. Further, when the content of K₂O is too large, the strain point is liable to lower, the thermal expansion coefficient increases excessively, and the thermal shock resistance is liable to lower. As a result, the glass sheet is liable to have thermal shrinkage and thermal deformation, and to have a crack in a heat treatment step at the time of producing a PDP or the like. On the other hand, when the content of K₂O is too small, the above-mentioned effects are hardly provided. Thus, the content of K₂O is 0.1 to 20%, preferably 2 to 10%, more preferably 3 to 8%.

ZrO₂ is a component that increases the strain point without increasing the viscosity at high temperature. However, when the content of ZrO₂ is too large, the density is liable to increase, and the resultant glass sheet is easily broken. Besides, devitrified crystals of the ZrO₂ system are liable to precipitate and a glass sheet is difficult to be formed. Further, zircon, which is a material for introducing ZrO₂, comprises relatively much Fe₂O₃ as an impurity. Thus, in order to satisfy a demand for a high transmittance, the use amount of ZrO₂ is restricted. Besides, ZrO₂ is a component that increases the refractive index, and hence has the effect of increasing the reflectance at the interface between glass and air to decrease the transmittance. Thus, the content of ZrO₂ is 0 to 10%, preferably 0.1 to 9%, more preferably 2 to 8%.

Fe is present in the state of Fe²⁺ or Fe³⁺ in glass, and Fe²⁺ has particularly strong light absorption properties in the range of from the visible long-wavelength region to the near-infrared region. General-purpose soda-lime glass comprises much Fe₂O₃ derived from material impurities. High strain point glass typified by a substrate for a PDP comprises much Fe₂O₃ for adjusting the color tone thereof or as a material impurity. The lower limit of the total iron content is based on the restriction of the use of a material having a low iron content from the viewpoint of reducing the cost. Particularly when zircon is used as a material for introducing ZrO₂, the lower limit of the total iron content is restricted because of the existence of iron impurities derived from zircon. In order to satisfy a demand for a high transmittance, the content of Fe₂O₃ is 0 to less than 0.04%, preferably 0.001 to 0.0.035%, more preferably 0.005 to 0.030%, still more preferably 0.01 to 0.025%.

SO₃ is a component that acts as a fining agent. Further, the content of SO₃ in glass contributes to changing the valence of Fe and the transmittance of the glass, and hence the content of SO₃ needs to be optimized from the viewpoint of the transmittance. The content of SO₃ is 0 to 0.5%, preferably 0.005 to 0.1%, more preferably 0.01 to 0.07%, still more preferably 0.015 to 0.05%. When the content of SO₃ is too large, SO₂ dissolved in glass is liable to re-evaporate, easily causing a bubble defect. FIG. 1 shows data on a relationship between the transmittance of glass with a thickness of 1.8 mm at a wavelength 1,100 nm and the residual SO₃ amount in the glass. Note that in FIG. 1, data on Sample Nos. 2 to 8, which have the same mother composition and the same total iron content but each have different SO₃ contents, are plotted. Note that, when glass sheets are formed by a float method, the glass sheets can be produced in a large quantity at low cost, but in this case, it is preferred to use sodium sulfate decahydrate as a fining agent.

In addition to the above-mentioned components, for example, the following components may be added.

TiO₂ is a component that prevents coloring by ultraviolet light and enhances the climate resistance. However, when the content of TiO₂ is too large, glass is liable to denitrify and to be colored into a brownish-red color. Besides, TiO₂ is a component that increases the refractive index, and hence has the effect of increasing the reflectance at the interface between glass and air to decrease the transmittance. Thus, the content of TiO₂ is preferably 0 to 10%, particularly preferably 0 to less than 0.1%.

P₂O₅ is a component that enhances the devitrification resistance, is a component that particularly suppresses the precipitation of devitrified crystals of the ZrO₂ system, and is a component that prevents a glass sheet from being easily broken. However, when the content of P₂O₅ is too large, glass is liable to have phase separation in an opaque white color. Thus, the content of P₂O₅ is preferably 0 to 10%, 0 to 0.2%, particularly preferably 0 to less than 0.1%.

ZnO is a component that reduces the viscosity at high temperature. When the content of ZnO is too large, the devitrification resistance is liable to deteriorate. Thus, the content of ZnO is preferably 0 to 10%, particularly preferably 0 to 5%.

CeO₂ is a component that acts as a fining agent and an oxidizing agent and is a component that has a high ability to produce trivalent Fe and is effective for improving the transmittance in the range of from the visible long-wavelength region to the near-infrared wavelength region. On the other hand, CeO₂ has a great effect of turning the color of glass to a yellow color, and hence the use amount thereof is preferably restricted. Thus, the content of CeO₂ is preferably 0 to 2%, particularly preferably 0 to 1%, and it is desirable that CeO₂ be not contained except CeO₂ as an unavoidable impurity (such as less than 0.1%).

The content of As₂O₃ is preferably 0 to 1%, particularly preferably 0 to less than 0.1%. As₂O₃ is a component that acts as a fining agent and an oxidizing agent, but is a component that colors glass when a glass sheet is formed by a float method and a component that may give a load to the environment.

The content of Sb₂O₃ is preferably 0 to 1%, particularly preferably 0 to less than 0.1%. Sb₂O₃ is a component that acts as a fining agent and an oxidizing agent, is a component that has a high ability to produce trivalent Fe but colors glass when a glass sheet is formed by a float method, and is a component that may give a load to the environment.

The content of SnO₂ is preferably 0 to 1%, particularly preferably 0 to less than 0.1%. SnO₂ is a component that acts as a fining agent and an oxidizing agent but is a component that deteriorates the denitrification resistance.

In addition to the above-mentioned components, each of F and Cl may be added up to 1% in total in order to enhance the meltability, fining property, and formability. Moreover, each of Nb₂O₅, HfO₂, Ta₂O₅, Y₂O₃, and La₂O₃ may be added up to 3% in order to enhance the chemical durability. Further, metal oxides except the above-mentioned oxides may be added up to 2% in total in order to adjust the redox.

The transmittance of the glass according to this embodiment with a thickness of 1.8 mm at a wavelength 1,100 nm is 86 to 92%, preferably 88 to 92%, more preferably 89 to 92%. When the transmittance is too low, the power consumption of a display such as a PDP may increase and the conversion efficiency of a solar cell or the like may deteriorate. On the other hand, the upper limit of the transmittance is restricted in relation to various characteristics. For example, when the thermal expansion coefficient is restricted to 70×10⁻⁷ to 100×10⁻⁷/° C. and the strain point is restricted to 520 to 700° C., the refractive index nd of glass is 1.50 or more. In this case, the upper limit of the transmittance is substantially limited to 92% or less because the light reflection at the interface between the glass and air is taken into consideration. Further, when the viscosity at high temperature and liquidus viscosity are taken into consideration in addition to the above-mentioned thermal expansion coefficient and strain point, the refractive index nd of glass is 1.54 or more. In this case, the upper limit of the transmittance is substantially limited to less than 91%.

The mass ratio of Fe²⁺ in terms of FeO with respect to a total iron content (t-Fe) in terms of Fe₂O₃, that is, Fe²⁺/t-Fe is preferably 0.7 or less, particularly preferably 0.1 to 0.7. When the value of Fe²⁺/t-Fe is too large, glass is liable to be colored to an amber color by iron sulfide. Note that, when the value of Fe²⁺/t-Fe is too small, glass is liable to be colored to a pale yellow color by Fe³⁺.

Fe²⁺/t-Fe in glass is preferably changed by, for example, adjusting the amount of a reducing agent added to a glass material. When a glass sheet is formed by a float method, sodium sulfate decahydrate is generally used. In this case, by adjusting the amount of sodium sulfate decahydrate or adding carbon as a reducing agent, Fe²⁺/t-Fe can be changed. Note that carbon also has the effect of lowering the decomposition temperature of sodium sulfate decahydrate in glass. The addition amount of carbon is preferably 0.001 to 0.15 g, particularly preferably 0.003 to 0.09 g, with respect to 100 g of glass.

When a glass sheet is produced in a general-purpose float furnace, it is highly necessary to lower the value of Fe²⁺/t-Fe by adding CeO₂ and the like. However, in this case, the production cost of the glass sheet may significantly rise.

Meanwhile, Fe is present in glass in the state of Fe²⁺ or Fe³⁺ and acts as a fining agent. In order to reduce the residual SO₃ amount to suppress the reboiling of SO₃ in consideration of the refining action of Fe, it is preferred to increase the value of Fe²⁺/t-Fe (the mass ratio of Fe²⁺ in terms of FeO with respect to the total content of Fe²⁺ in terms of FeO and Fe³⁺ in terms of Fe₂O₃). Thus, the value of Fe²⁺/(Fe²⁺+Fe³⁺) is preferably 0.1 to 0.7%, 0.2 to 0.6, 0.3 to 0.5, particularly preferably 0.4 to 0.45.

The thermal expansion coefficient is preferably 70×10⁻⁷ to 100×10⁻⁷/° C., particularly preferably 80×10⁻⁷ to 90×10⁻⁷/° C. With this, the thermal expansion coefficient can be easily matched with those of peripheral members such as a seal frit and a photoelectric conversion film. Note that, when the thermal expansion coefficient is too high, the thermal shock resistance is liable to deteriorate, with the result that the glass sheet is liable to have a crack in a heat treatment step at the time of producing a display such as a PDP or a solar cell such as a CIS-based solar cell, a CdTe-based solar cell, or a dye-sensitized solar cell.

The density is preferably 2.90 g/cm³ or less, particularly preferably 2.85 g/cm³ or less. With this, the costs of a display such as a PDP and supporting members for various solar cells can be easily reduced. Note that the “density” can be measured by a well-known Archimedes method.

The strainpoint is preferably 550 to 700° C., 570 to 680° C., particularly preferably 600 to 650° C. With this, the glass sheet is less likely to have thermal shrinkage and thermal deformation in a heat treatment step at the time of producing a display such as a PDP or various solar cells. Particularly when a method involving transporting CdTe in the state of steam and forming a film is adopted in a production step of a CdTe-based solar cell, the use of a glass sheet having a higher strain point enables increasing a film-forming rate, and hence the use is useful for reducing takt time.

The temperature at 10^{4.0} dPa·s is preferably 1,200° C. or less, particularly preferably 1,180° C. or less. With this, the glass sheet can be easily formed at low temperature. Herein, the “temperature at 10^{4.0} dPa·s” can be measured by a platinum sphere pull up method.

The temperature at 10^{2.5} dPa·s is preferably 1,520° C. or less, particularly preferably 1,460° C. or less. With this, a glass material can be easily melted at low temperature. Herein, the “temperature at 10^{2.5} dPa·s” can be measured by a platinum sphere pull up method.

The liquidus temperature is preferably 1,160° C. or less, particularly preferably 1,100° C. or less. As the liquidus temperature increases, glass is liable to devitrify at the time of forming and the formability is liable to lower. Herein, the “liquidus temperature” refers to a value obtained by measuring a temperature at which crystals of glass precipitate after glass powder that has passed through a standard 30-mesh sieve (500 μm) and remained on a 50-mesh sieve (300 μm) is placed in a platinum boat and then the platinum boat is kept for 24 hours in a gradient heating furnace.

The liquidus viscosity is preferably 10^{4.0} dPa·s or more, particularly preferably 10^{4.0} dPa·s or more. As the liquidus viscosity decreases, glass is liable to devitrify at the time of forming and the formability is liable to lower. Herein, the “liquidus viscosity” refers to a value obtained by measuring the viscosity of glass at a liquidus temperature by a platinum sphere pull up method. Note that, as the liquidus temperature is lower or as the liquidus viscosity is higher, the denitrification resistance improves, and hence devitrified crystals hardly precipitate in glass at the time of forming. As a result, large glass sheets can be easily manufactured at low cost.

The volume electric resistivity (150° C.) is preferably 11.0 or more, particularly preferably 11.5 or more. With this, alkali components hardly react with an electrode such as an ITO film, and consequently, the electric resistance of the electrode hardly changes. Herein, the “volume electric resistivity (150° C.)” refers to a value measured at 150° C. on the basis of ASTM C657-78.

The dielectric constant is preferably 8 or less, 7.9 or less, particularly preferably 7.8 or less. With this, the amount of an electric current necessary for causing a cell to emit light once decreases, and hence the power consumption of a PDP or the like is likely to be reduced. Herein, the “dielectric constant” refers to a value measured under the conditions of 25° C. and 1 MHz on the basis of ASTM D150-87.

The dielectric dissipation factor is preferably 0.05 or less, 0.01 or less, particularly preferably 0.005 or less. When the dielectric dissipation factor increases, the application of a voltage to a pixel electrode or the like causes the glass to generate heat, with the result that the operating characteristics of a PDP or the like may be adversely affected. Herein, the “dielectric dissipation factor” refers to a value measured under the conditions of 25° C. and 1 MHz on the basis of ASTM D150-87.

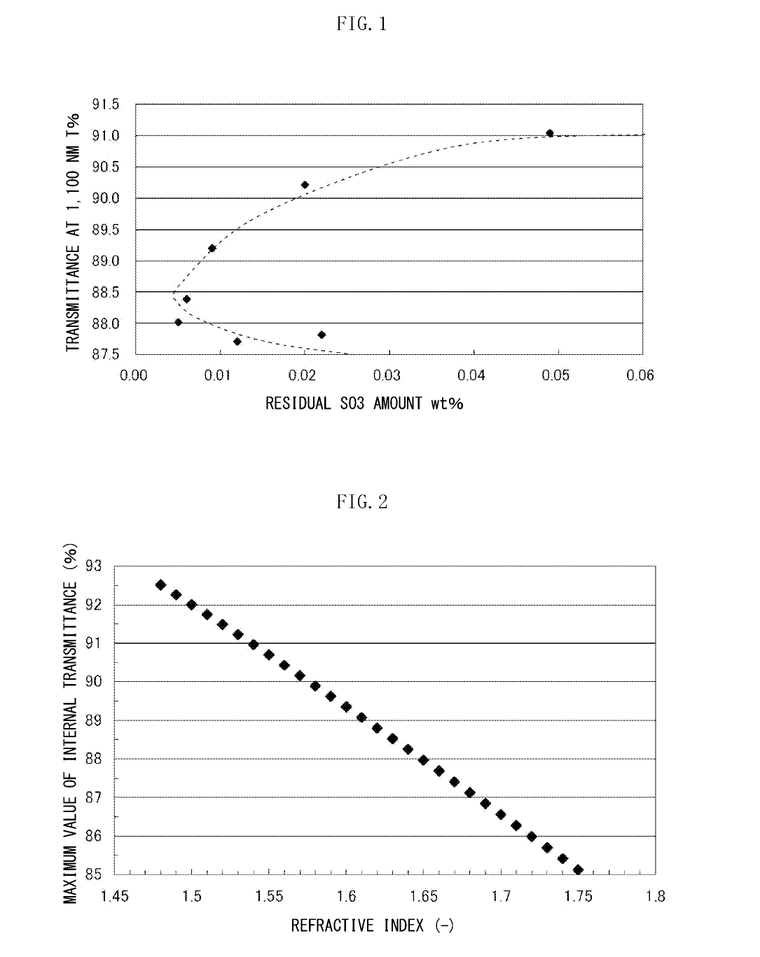

The refractive index nd is preferably 1.50 to 1.72, 1.53 to 1.60, particularly preferably 1.54 to 1.58. When the refractive index is less than 1.50, it is difficult to restrict the thermal expansion coefficient to 70×10⁻⁷ to 100×10⁻⁷/° C. and the strain point to 520 to 700° C., and hence it is difficult to use the glass sheet in a display or for a solar cell. On the other hand, when the refractive index is more than 1.72, light reflection at the interface between glass and air increases, and the transmittance of the glass sheet with a thickness of 1.8 mm at a wavelength 1,100 nm is liable to be less than 86%. As a result, the power consumption of a display such as a PDP increases and the conversion efficiency of a solar cell deteriorates. For reference, FIG. 2 shows data on refractive index dependence of the maximum value of an internal transmittance measured in consideration of reflection at the interface between glass and air.

The Young's modulus is preferably 78 GPa or more, particularly preferably 80 GPa or more, and the specific Young's modulus is preferably 27.5 GPa/(g/cm³) or more, particularly preferably 28 GPa/(g/cm³) or more. With this, the glass sheet hardly bends, and hence, when the glass sheet is handled in a transportation step or a packing step, it is unlikely that the glass sheet significantly swings to drop or the glass sheet comes into contact with another member to be damaged. Herein, the “Young's modulus” refers to a value measured by a resonance method. The “specific Young's modulus” refers to a value obtained by dividing the Young's modulus by the density.

The visible light transmittance of the glass sheet with a thickness of 3.2 mm is preferably 86 to 92%, particularly preferably 86 to less than 90%. With this, while the production cost of the glass sheet is suppressed, a reduction in power consumption of a display or an increase in efficiency of a solar cell is likely to be achieved. Herein, the “visible light transmittance” is a value measured on the basis of JIS R3106, and illuminant C was used as an illuminant for measuring the visible light transmittance. Note that when the thickness of a sample is more than 3.2 mm, the sample is polished so as to have a thickness of 3.2 mm, followed by measurement, and when the thickness of a sample is less than 3.2 mm, the conversion of a thickness can be performed by using Mathematical Equation 1, where nx=nd.

The solar transmittance of the glass sheet with a thickness of 3.2 mm is preferably 85 to 89%, particularly preferably 85 to less than 87.5%. With this, while the production cost of the glass sheet is suppressed, a reduction in power consumption of a display or an increase in efficiency of a solar cell is likely to be achieved. Herein, the “solar transmittance” is a value measured on the basis of JIS R3106. Note that when the thickness of a sample is more than 3.2 mm, the sample is polished so as to have a thickness of 3.2 mm, followed by measurement, and that when the thickness of a sample is less than 3.2 mm, the conversion of a thickness can be performed by using Mathematical Equation 1, where nx=nd.

The transmittance of the glass according to this embodiment with a thickness of 1.8 mm at a wavelength 1,100 nm is a value measured in a state in which an anti-reflective film, a transparent conductive film, and the like are not formed on the glass. When an anti-reflective film is formed on the glass sheet, the transmittance can be further increased. Meanwhile, when a transparent conductive film is formed on the glass sheet, the glass sheet can be applied to various devices more easily.

The glass according to this embodiment can be manufactured by loading a glass material, which is prepared so as to have a glass composition in the above-mentioned glass composition range, into a continuous melting furnace, heating and melting the glass material, then removing bubbles from the resultant glass melt, feeding the glass melt into a forming apparatus, and forming the glass melt into a sheet shape or the like, followed by annealing.

It is possible to exemplify, as a method of forming a glass sheet, a float method, a slot down-draw method, an overflow down-draw method, and a redraw method. When inexpensive glass sheets are produced in a large quantity, a float method is preferably adopted.

### Examples

Examples of the present invention are described below. Note that Examples described below are merely for illustrative purposes. The present invention is by no means limited to Examples described below.

Tables 1 to 4 show Examples of the present invention (Sample Nos. 2 to 11 and 13 to 27) and Comparative Examples (Sample Nos. 1 and 12).

TABLE 1

| | | Comparative | | | | | | | |
|---|---|---|---|---|---|---|---|---|---|
| | | Example | Example | | | | | | |
| | | No. 1 | No. 2 | No. 3 | No. 4 | No. 5 | No. 6 | No. 7 | No. 8 |
| Glass | SiO₂ | 58 | 55 | 55 | 55 | 55 | 55 | 55 | 55 |
| composition | Al₂O₃ | 7 | 7 | 7 | 7 | 7 | 7 | 7 | 7 |
| (wt %) | MgO | 2 | 2 | 2 | 2 | 2 | 2 | 2 | 2 |
| | CaO | 5 | 2 | 2 | 2 | 2 | 2 | 2 | 2 |
| | SrO | 7 | 9 | 9 | 9 | 9 | 9 | 9 | 9 |
| | BaO | 8 | 9 | 9 | 9 | 9 | 9 | 9 | 9 |
| | Na₂O | 4 | 4 | 4 | 4 | 4 | 4 | 4 | 4 |
| | K₂O | 6 | 7 | 7 | 7 | 7 | 7 | 7 | 7 |
| | ZrO₂ | 2 | 5 | 5 | 5 | 5 | 5 | 5 | 5 |
| | Sb₂O₃ | — | — | — | — | — | — | — | — |
| | SO₃ | 0.030 | 0.049 | 0.020 | 0.009 | 0.006 | 0.005 | 0.012 | 0.022 |

| | | | | | | | | |
|---|---|---|---|---|---|---|---|---|
| Carbon addition amount | 0.062 | 0.055 | 0.069 | 0.073 | 0.076 | 0.083 | 0.096 | 0.110 |
| (g) | | | | | | | | |
| (with respect to 100 g | | | | | | | | |
| of glass) | | | | | | | | |
| t-Fe (wt %) | 0.105 | 0.021 | 0.021 | 0.021 | 0.021 | 0.021 | 0.021 | 0.021 |
| Fe²⁺ (wt %) | 0.036 | 0.004 | 0.007 | 0.009 | 0.012 | 0.014 | Not | Not |
| | | | | | | | measured | measured |
| Fe³⁺ (wt %) | 0.065 | 0.016 | 0.013 | 0.011 | 0.008 | 0.005 | Not | Not |
| | | | | | | | measured | measured |
| Fe²⁺/t-Fe | 0.38 | 0.23 | 0.36 | 0.49 | 0.61 | 0.76 | Not | Not |
| | | | | | | | measured | measured |
| α (×10⁻⁷/° C.) | 84 | 84 | 84 | 84 | 84 | 84 | 84 | 84 |
| d (g/cm³) | 2.82 | 2.82 | 2.82 | 2.82 | 2.82 | 2.82 | 2.82 | 2.82 |
| Ps (° C.) | 580 | 580 | 580 | 580 | 580 | 580 | 580 | 580 |
| Ta (° C.) | 630 | 630 | 630 | 630 | 630 | 630 | 630 | 630 |
| Ts (° C.) | 840 | 840 | 840 | 840 | 840 | 840 | 840 | 840 |
| 10⁴ dPa · s (° C.) | 1,150 | 1,150 | 1,150 | 1,150 | 1,150 | 1,150 | 1,150 | 1,150 |
| 10^{2.5} dPa · s (° C.) | 1,410 | 1,410 | 1,410 | 1,410 | 1,410 | 1,410 | 1,410 | 1,410 |
| TL (° C.) | 1,010 | 1,010 | 1,010 | 1,010 | 1,010 | 1,010 | 1,010 | 1,010 |
| log₁₀ηTL (dPa · s) | 5.2 | 5.2 | 5.2 | 5.2 | 5.2 | 5.2 | 5.2 | 5.2 |
| ρ 150° C. log₁₀(Ω · m) | 12.2 | 12.2 | 12.2 | 12.2 | 12.2 | 12.2 | 12.2 | 12.2 |
| ρ 250° C. log₁₀(Ω · m) | 9.6 | 9.6 | 9.6 | 9.6 | 9.6 | 9.6 | 9.6 | 9.6 |
| ρ 350° C. log₁₀(Ω · m) | 7.8 | 7.8 | 7.8 | 7.8 | 7.8 | 7.8 | 7.8 | 7.8 |
| ε | 7.6 | 7.6 | 7.6 | 7.6 | 7.6 | 7.6 | 7.6 | 7.6 |
| tanδ | 0.003 | 0.003 | 0.003 | 0.003 | 0.003 | 0.003 | 0.003 | 0.003 |
| Young's modulus | 77 | 77 | 77 | 77 | 77 | 77 | 77 | 77 |
| (GPa) | | | | | | | | |
| Specific Young's | 27 | 27 | 27 | 27 | 27 | 27 | 27 | 27 |
| modulus | | | | | | | | |
| nd | 1.55 | 1.55 | 1.55 | 1.55 | 1.55 | 1.55 | 1.55 | 1.55 |
| Transmittance at 1,100 | 81.1 | 91.0 | 90.2 | 89.2 | 88.4 | 88.0 | 87.7 | 87.8 |
| nm (%) | | | | | | | | |
| Visible transmittance | Not | 89.7 | 90.6 | 88.6 | 87.4 | 87.0 | 83.7 | 80.8 |
| (%) | measured | | | | | | | |
| Solar transmittance | Not | 87.1 | 88.9 | 86.5 | 86.0 | 84.8 | 81.3 | 79.7 |
| (%) | measured | | | | | | | |

TABLE 2

| | | | | | Comparative | | | | |
|---|---|---|---|---|---|---|---|---|---|
| | | Example | | | Example | Example | | | |
| | | No. 9 | No. 10 | No. 11 | No. 12 | No. 13 | No. 14 | No. 15 | No. 16 |
| Glass | SiO₂ | 49.9 | 52.0 | 54.8 | 71.7 | 62.0 | 59.0 | 55.4 | 63.6 |
| composition | Al₂O₃ | 12.0 | 14.0 | 7.0 | 1.7 | 13.0 | 19.0 | 5.5 | 7.1 |
| (wt %) | MgO | 0.1 | 1.0 | 2.0 | 4.2 | 7.0 | 2.0 | 2.0 | 5.1 |
| | CaO | 6.0 | 5.0 | 2.0 | 8.5 | 0.2 | 3.0 | 2.5 | 3.5 |
| | SrO | 12.0 | 11.0 | 9.0 | — | 0.1 | — | 8.9 | 6.5 |
| | BaO | 4.0 | 3.0 | 9.0 | — | 0.1 | — | 8.5 | 0.1 |
| | Na₂O | 7.0 | 5.0 | 4.0 | 13 | 11.5 | 13.0 | 4.1 | 1.8 |
| | K₂O | 5.0 | 4.0 | 7.0 | 0.7 | 6.1 | 4.0 | 6.5 | 11.8 |
| | ZrO₂ | 4.0 | 5.0 | 5.0 | — | — | — | 6.6 | 0.5 |
| | Sb₂O₃ | — | — | 0.2 | — | — | — | — | — |
| | SO₃ | 0.027 | 0.028 | 0.010 | 0.120 | 0.018 | 0.018 | 0.025 | 0.016 |

| | | | | | | | | |
|---|---|---|---|---|---|---|---|---|
| Carbon addition amount | 0.068 | 0.067 | 0.000 | 0.066 | 0.070 | 0.071 | 0.07 | 0.069 |
| (g) | | | | | | | | |
| (with respect to 100 g | | | | | | | | |
| of glass) | | | | | | | | |
| t-Fe (wt %) | 0.023 | 0.038 | 0.022 | 0.025 | 0.025 | 0.021 | 0.021 | 0.021 |
| Fe²⁺ (wt %) | 0.009 | 0.013 | Not | 0.008 | 0.009 | 0.008 | 0.008 | 0.008 |
| | | | measured | | | | | |
| Fe³⁺ (wt %) | 0.013 | 0.024 | Not | 0.016 | 0.015 | 0.012 | 0.012 | 0.012 |
| | | | measured | | | | | |
| Fe²⁺/t-Fe | 0.42 | 0.38 | Not | 0.36 | 0.40 | 0.41 | 0.41 | 0.41 |
| | | | measured | | | | | |
| α (×10⁻⁷/° C.) | 84 | 84 | 84 | 87 | 96 | 92 | 81 | 81 |
| d (g/cm³) | 2.82 | 2.82 | 2.82 | 2.50 | 2.48 | 2.45 | 2.86 | 2.55 |
| Ps (° C.) | 620 | 620 | 580 | 510 | 550 | 590 | 600 | 600 |
| Ta (° C.) | 660 | 660 | 630 | 550 | 600 | 630 | 650 | 650 |
| Ts (° C.) | 860 | 860 | 840 | 730 | 830 | 860 | 860 | 880 |
| 10⁴ dPa · s (° C.) | 1,150 | 1,150 | 1,150 | 1,030 | 1,170 | Not | 1,160 | 1,220 |
| | | | | | | measured | | |
| 10^{2.5} dPa · s (° C.) | 1,400 | 1,400 | 1,410 | 1,330 | 1,480 | Not | 1,410 | 1,519 |
| | | | | | | measured | | |
| TL (° C.) | 1,100 | 1,100 | 1,010 | 1,010 | 1,110 | Not | 970 | 1,110 |
| | | | | | | measured | | |
| log₁₀ηTL (dPa · s) | 4.4 | 4.4 | 5.2 | 4.3 | 4.4 | Not | 6.0 | 4.8 |
| | | | | | | measured | | |
| ρ 150° C. log₁₀(Ω · m) | 11.4 | 11.4 | 12.2 | 8.6 | 8.2 | Not | 12.2 | 11.6 |
| | | | | | | measured | | |
| ρ 250° C. log₁₀(Ω · m) | 8.9 | 8.9 | 9.6 | 6.7 | 6.4 | Not | 9.6 | 9.0 |
| | | | | | | measured | | |
| ρ 350° C. log₁₀(Ω · m) | 7.2 | 7.2 | 7.8 | 5.4 | 5.1 | Not | 7.8 | 7.2 |
| | | | | | | measured | | |
| ε | 7.8 | 7.8 | 7.6 | 7.1 | 7.3 | Not | 7.6 | 7.8 |
| | | | | | | measured | | |
| tanδ | 0.003 | 0.003 | 0.003 | 0.008 | 0.008 | Not | 0.003 | 0.003 |
| | | | | | | measured | | |
| Young's modulus (GPa) | 81 | 82 | 77 | 73 | 73 | Not | 77 | Not |
| | | | | | | measured | | measured |
| Specific Young's | 29 | 29 | 27 | 29 | 30 | Not | 27 | Not |
| modulus | | | | | | measured | | measured |
| nd | 1.57 | 1.56 | 1.56 | 1.52 | 1.53 | 1.52 | 1.56 | 1.53 |
| Transmittance at 1,100 | 90.9 | 89.0 | 90.6 | 91.8 | 91.0 | 90.4 | 90.2 | 90.1 |
| nm (%) | | | | | | | | |
| Visible transmittance | 89.0 | 88.0 | Not | 91.2 | Not | Not | Not | Not |
| (%) | | | measured | | measured | measured | measured | measured |
| Solar transmittance | 87.4 | 86.5 | Not | 90.0 | Not | Not | Not | Not |
| (%) | | | measured | | measured | measured | measured | measured |

TABLE 3

| | | Example | | | | | | |
|---|---|---|---|---|---|---|---|---|
| | | No. 17 | No. 18 | No. 19 | No. 20 | No. 21 | No. 22 | No. 23 |
| Glass | SiO₂ | 60.5 | 52.9 | 54.4 | 56.0 | 56.0 | 55.0 | 51.0 |
| composition | Al₂O₃ | 9.7 | 13.8 | 7.1 | 9.0 | 4.0 | 9.0 | 12.5 |
| (wt %) | MgO | 5.1 | 3.3 | 4.0 | 1.0 | 0.0 | 10.0 | 1.0 |
| | CaO | 5.9 | 4.3 | 2.1 | 2.0 | 9.0 | 0.0 | 5.5 |
| | SrO | 1.6 | — | 8.9 | 9.0 | 3.0 | 7.0 | 12.0 |
| | BaO | 0.1 | 7.5 | 8.5 | 9.0 | 9.0 | 7.0 | 3.5 |
| | Na₂O | 2.6 | 11.3 | 8.7 | 4.0 | 4.0 | 4.0 | 6.0 |
| | K₂O | 9.4 | 3.2 | 0.1 | 7.0 | 7.0 | 7.0 | 4.0 |
| | ZrO₂ | 5.1 | 3.7 | 6.2 | 3.0 | 8.0 | 1.0 | 4.5 |
| | Sb₂O₃ | — | — | — | — | — | — | — |
| | SO₃ | 0.017 | 0.018 | 0.022 | 0.022 | 0.022 | 0.022 | 0.065 |

| | | | | | | | |
|---|---|---|---|---|---|---|---|
| Carbon addition amount | 0.070 | 0.068 | 0.070 | 0.070 | 0.069 | 0.075 | 0.075 |
| (g) | | | | | | | |
| (with respect to 100 g | | | | | | | |
| of glass) | | | | | | | |
| t-Fe (wt %) | 0.021 | 0.019 | 0.022 | 0.034 | 0.022 | 0.030 | 0.021 |
| Fe²⁺ (wt %) | 0.008 | 0.006 | 0.008 | 0.013 | 0.008 | 0.012 | 0.009 |
| Fe³⁺ (wt %) | 0.012 | 0.012 | 0.013 | 0.020 | 0.013 | 0.017 | 0.011 |
| Fe²⁺/t-Fe | 0.41 | 0.35 | 0.40 | 0.42 | 0.42 | 0.45 | 0.50 |
| α (×10⁻⁷/° C.) | 85 | 92 | 80 | 84 | 84 | 84 | 84 |
| d (g/cm³) | 2.56 | 2.45 | 2.88 | 2.82 | 2.82 | 2.82 | 2.82 |
| Ps (° C.) | 590 | 590 | 580 | 580 | 580 | 580 | 620 |
| Ta (° C.) | 640 | 630 | 640 | 630 | 630 | 630 | 660 |
| Ts (° C.) | 850 | 860 | 830 | 840 | 840 | 840 | 860 |
| 10⁴ dPa · s (° C.) | 1,180 | Not | 1,130 | 1,150 | 1,150 | 1,150 | 1,150 |
| | | measured | | | | | |
| 10^{2.5} dPa · s (° C.) | 1,470 | Not | 1,400 | 1,410 | 1,410 | 1,420 | 1,400 |
| | | measured | | | | | |
| TL(° C.) | Not | Not | Not | 1,010 | 1,010 | 1,010 | 1,100 |
| | measured | measured | measured | | | | |
| log₁₀ηTL (dPa · s) | Not | Not | Not | 5.2 | 5.2 | 5.1 | 4.4 |
| | measured | measured | measured | | | | |
| ρ 150° C. log₁₀(Ω · m) | 10.9 | Not | Not | 12.2 | 11.8 | 12.2 | 11.4 |
| | | measured | measured | | | | |
| ρ 250° C. log₁₀(Ω · m) | 8.4 | Not | Not | 9.6 | 9.8 | 9.6 | 8.9 |
| | | measured | measured | | | | |
| ρ 350° C. log₁₀(Ω · m) | 6.8 | Not | Not | 7.8 | 7.4 | 7.8 | 7.2 |
| | | measured | measured | | | | |
| ε | 7.3 | Not | Not | 7.6 | 7.6 | 7.6 | 7.8 |
| | | measured | measured | | | | |
| tanδ | 0.003 | Not | Not | 0.003 | 0.003 | 0.003 | 0.003 |
| | | measured | measured | | | | |
| Young's modulus(GPa) | 77 | Not | Not | 77 | 77 | 77 | 82 |
| | | measured | measured | | | | |
| Specific Young's | 30 | Not | Not | 27 | 27 | 27 | 29 |
| modulus | | measured | measured | | | | |
| nd | 1.52 | 1.52 | 1.54 | 1.55 | 1.55 | 1.55 | 1.56 |
| Transmittance at 1,100 | 91.3 | 91.0 | 90.8 | 88.2 | 88.2 | 88.2 | 88.3 |
| nm (%) | | | | | | | |
| Visible transmittance | Not | Not | Not | Not | Not | Not | Not |
| (%) | measured | measured | measured | measured | measured | measured | measured |
| Solar transmittance | Not | Not | Not | Not | Not | Not | Not |
| (%) | measured | measured | measured | measured | measured | measured | measured |

TABLE 4

| | | Example | | | |
|---|---|---|---|---|---|
| | | No. 24 | No. 25 | No. 26 | No. 27 |
| Glass composition | SiO₂ | 61.3 | 65 | 55.8 | 55.8 |
| (wt %) | Al₂O₃ | 9.5 | 5.5 | 18.5 | 17 |
| | MgO | 7 | 8 | 4.5 | 5.5 |
| | CaO | 4.5 | 3.3 | 2.5 | 3 |
| | SrO | 1 | 0 | 1.5 | 1.5 |
| | BaO | 0.5 | 0 | 2.5 | 1 |
| | Na₂O | 5 | 3.5 | 9 | 7.5 |
| | K₂O | 7.5 | 10.5 | 3.5 | 6.5 |
| | ZrO₂ | 3.5 | 4 | 2 | 2 |
| | Sb₂O₃ | 0 | 0 | 0 | 0 |
| | SO₃ | 0.017 | 0.016 | 0.016 | 0.018 |

| | | | | |
|---|---|---|---|---|
| Carbon addition amount (g) | 0.070 | 0.069 | 0.072 | 0.071 |
| (with respect to 100 g of glass) | | | | |
| t-Fe (wt %) | 0.025 | 0.021 | 0.021 | 0.021 |
| Fe²⁺ (wt %) | 0.009 | 0.008 | 0.008 | 0.008 |
| Fe³⁺ (wt %) | 0.015 | 0.012 | 0.012 | 0.012 |
| Fe²⁺/t-Fe | 0.40 | 0.41 | 0.41 | 0.41 |
| α (×10⁻⁷/° C.) | 76 | 76 | 79 | 85 |
| d (g/cm³) | 2.51 | 2.55 | 2.57 | 2.56 |
| Ps (° C.) | 610 | 605 | 615 | 605 |
| Ta (° C.) | 650 | 650 | 660 | 650 |
| Ts (° C.) | 870 | 865 | 890 | 880 |
| 10⁴ dPa · s (° C.) | 1,220 | 1,200 | 1,240 | 1,230 |
| 10^{2.5} dPa · s (° C.) | 1,510 | 1,470 | 1,520 | 1,510 |
| TL (° C.) | 1,210 | 1,220 | 1,235 | 1,230 |
| log₁₀ηTL (dPa · s) | 4.1 | 3.9 | 4.0 | 4.0 |
| ρ 150° C. log₁₀(Ω · m) | Not measured | Not measured | Not measured | Not measured |
| ρ 250° C. log₁₀(Ω · m) | Not measured | Not measured | Not measured | Not measured |
| ρ 350° C. log₁₀(Ω · m) | Not measured | Not measured | Not measured | Not measured |
| ε | Not measured | Not measured | Not measured | Not measured |
| tanδ | Not measured | Not measured | Not measured | Not measured |
| Young's modulus (GPa) | Not measured | Not measured | Not measured | Not measured |
| Specific Young's modulus | Not measured | Not measured | Notmeasured | Not measured |
| nd | 1.53 | 1.53 | 1.52 | 1.52 |
| Transmittance at 1,100 nm (%) | 90.5 | 90.6 | 90.7 | 90.6 |
| Visible transmittance(%) | Not measured | Not measured | Not measured | Not measured |
| Solar transmittance (%) | Not measured | Not measured | Not measured | Not measured |

Sample Nos. 1 to 27 were produced in the following manner. First, batches in amounts corresponding to 300 g of glass blended so as to attain the glass compositions in the tables were loaded into a platinum crucible having a diameter of 80 mm and a height of 90 mm and were melted at 1,550° C. for 2 hours. The value of Fe²⁺/t-Fe was adjusted by adjusting the amounts of sodium sulfate decahydrate and carbon added in each of the batches. Note that the content of SO₃ in each of the batches was set to 0.2 mass % except for Sample No. 11. Tables 1 to 3 also describe carbon addition amounts with respect to 100 g of glass. Next, the resultant molten glass was poured on a carbon plate and was formed into a flat plate shape, followed by annealing. After that, predetermined processing was performed in accordance with each measurement. The residual SO₃ amount in the molten glass was measured by fluorescent X-ray analysis. The total iron content (t-Fe) and the contents of Fe²⁺ and Fe³⁺ were measured by chemical analysis. Note that the total iron content (t-Fe) is a value calculated in terms of Fe₂O₃, the content of Fe²⁺ is a value calculated in terms of FeO, and the content of Fe³⁺ is a value calculated in terms of Fe₂O₃.

The total iron content (t-Fe) and the contents of Fe²⁺ and Fe³⁺ were measured as follows. The content of Fe²⁺ was measured in the following manner. First, 15 ml of sulfuric acid were added into a Teflon bottle containing 0.5 g to 1.5 g of a sample, and the Teflon bottle was then put in a water bath set to 100° C., followed by heating for 10 minutes in an inert gas atmosphere. Next, 7 ml of hydrofluoric acid were added into the Teflon bottle, and the sample was again subjected to thermal decomposition for about 30 minutes in the water bath in an inert gas atmosphere. Subsequently, 6 g of boric acid were added into the Teflon bottle, followed by introduction of an inert gas, and the sample was again heated for about 10 minutes in the water bath. Further, while the state in which the inert gas was contained in the Teflon bottle was maintained, the sample was cooled, 0.5 ml of an o-phenanthroline solution was added as an indicator, and a N/200 Ce(SO₄)₂ solution was used to perform titration on the basis of the color change of the indicator from an orange color to a pale blue color. Finally, the content of Fe²⁺ was determined on the basis of the titer thereof. The total iron content was measured in the following manner. First, 0.3 g of a sample was weighed in a platinum dish, and the sample was decomposed by using 2 ml of nitric acid, 3 ml of sulfuric acid, and 20 ml of hydrofluoric acid. Subsequently, the decomposed sample was heated and melted in 10 ml of hydrochloric acid and H₂O, followed by filtration with 5 C filter paper. Finally, the volume of the sample was fixed at 100 ml, followed by the measurement of the total iron content (t-Fe) with an ICP emission spectrophotometer. Note that the content of Fe³⁺ is a value calculated from the total iron content (t-Fe) and the content of Fe²⁺.

Each of the resultant samples was evaluated for its thermal expansion coefficient α, density d, strain point Ps, annealing temperature Ta, softening temperature Ts, temperature at 10⁴ dPa·s, temperature at 10^{2.5} dPa·s, liquidus temperature TL, liquidus viscosity log₁₀ ηTL, volume electric resistivities ρ (150° C., 250° C., 350° C.), dielectric constant E, dielectric dissipation factor tan δ, Young's modulus, specific Young's modulus, refractive index nd, transmittance at 1,100 nm, visible transmittance, and solar transmittance. The results are shown in Tables.

The thermal expansion coefficient α refers to a value of an average thermal expansion coefficient in the temperature range of 30 to 380° C. measured with a dilatometer. Note that a cylindrical sample having a diameter of 5.0 mm and a length of 20 mm was used as a measurement sample.

The density d refers to a value measured by a well-known Archimedes method.

The strain point Ps, the annealing temperature Ta, and the softening temperature Ts are values measured on the basis of ASTM C336-71.

The temperature at 10⁴ dPa·s and the temperature at 102.5 dPa·s are values measured by a platinum sphere pull up method. Note that the temperature at 10⁴ dPa·s corresponds to a forming temperature.

The liquidus temperature TL refers to a value obtained by measuring a temperature at which crystals of glass are deposited after glass powder that has passed through a standard 30-mesh sieve (500 μm) and remained on a 50-mesh sieve (300 μm) is placed in a platinum boat and then the platinum boat is kept for 24 hours in a gradient heating furnace. The liquidus viscosity log₁₀ ηTL refers to a value obtained by measuring the viscosity of glass at a liquidus temperature TL by a platinum sphere pull up method.

The volume electric resistivity ρ refers to a value measured on the basis of ASTM C657-78 at each temperature.

The dielectric constant ∈ and the dielectric dissipation factor tan δ refer to values measured under the conditions of 25° C. and 1 MHz on the basis of ASTM D150-87.

The Young's modulus refers to a value measured by a resonance method. In addition, the specific Young's modulus refers to a value obtained by dividing the Young's modulus by the density.

The refractive index nd refers to a value measured using a refractometer (manufactured by Shimadzu Kalnew, KPR-2000) with a d-line (wavelength: 587.6 nm) of a helium lamp.

The transmittance at 1,100 nm refers to a value obtained by measuring the transmittance of a sample with a thickness of 1.8 mm at a wavelength of 1,100 nm with a general-purpose spectrophotometer equipped with an integrating sphere.

FIG. 3 shows a transmittance curve of Sample No. 1 with a thickness of 1.8 mm at a wavelength of 1,100 nm.

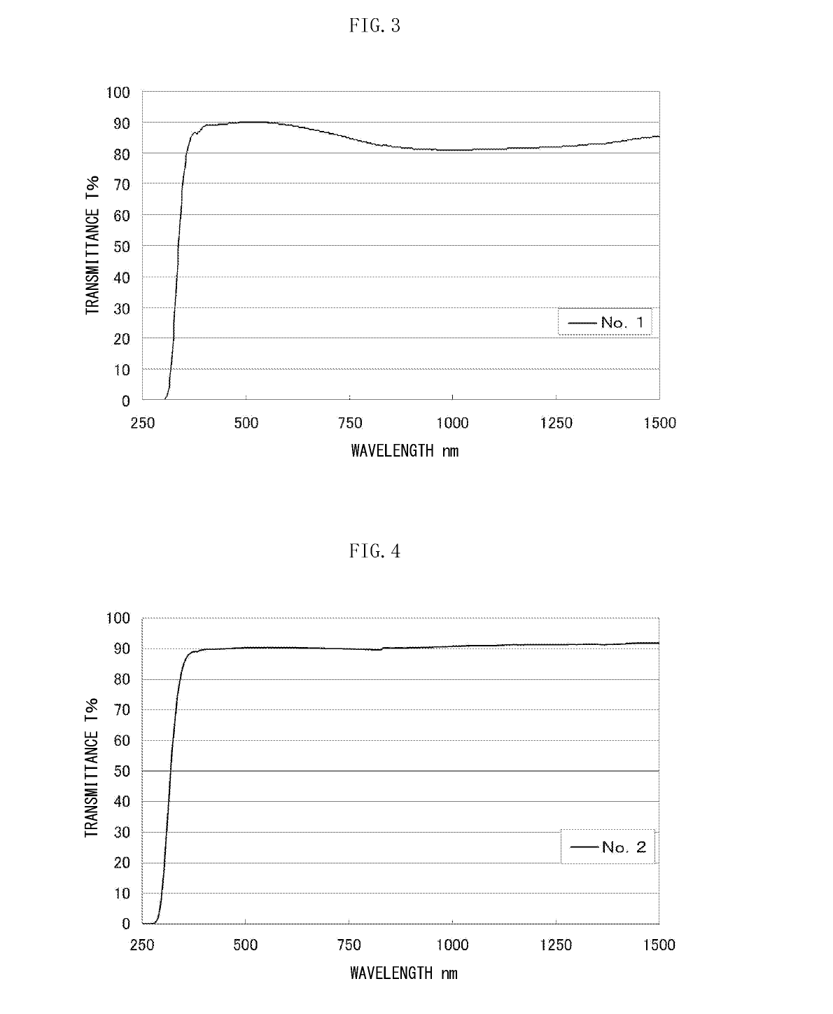

FIG. 4 shows a transmittance curve of Sample No. 2 with a thickness of 1.8 mm at a wavelength of 1,100 nm.

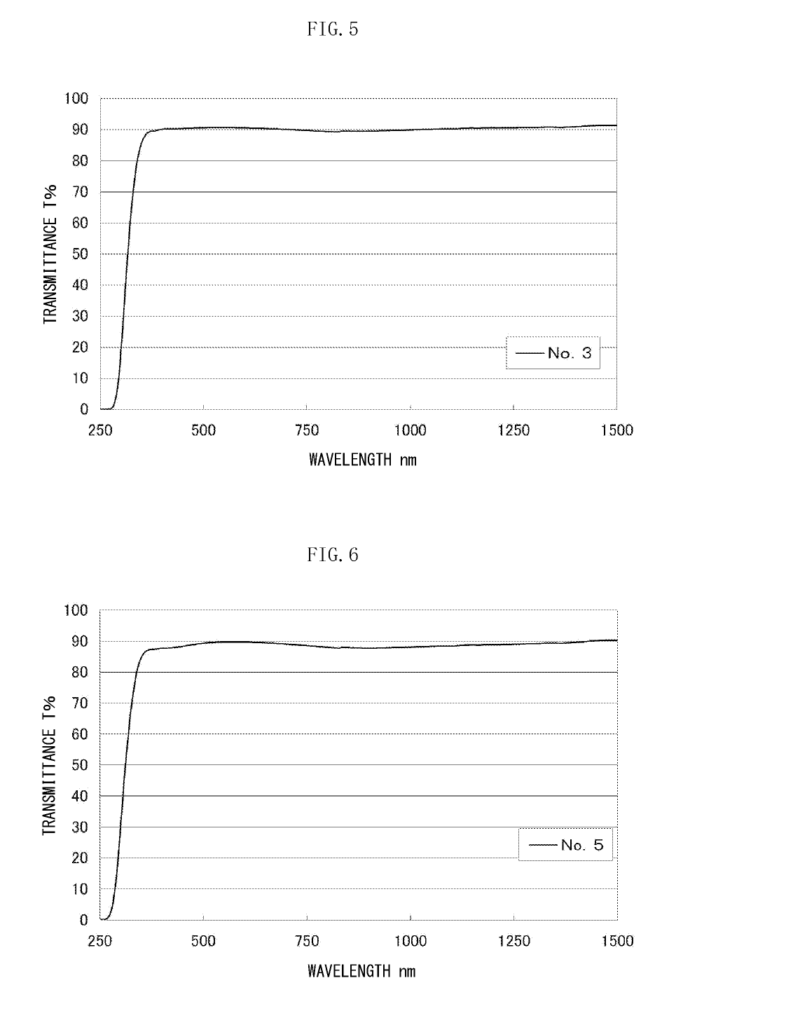

FIG. 5 shows a transmittance curve of Sample No. 3 with a thickness of 1.8 mm at a wavelength of 1,100 nm.

FIG. 6 shows a transmittance curve of Sample No. 5 with a thickness of 1.8 mm at a wavelength of 1,100 nm.

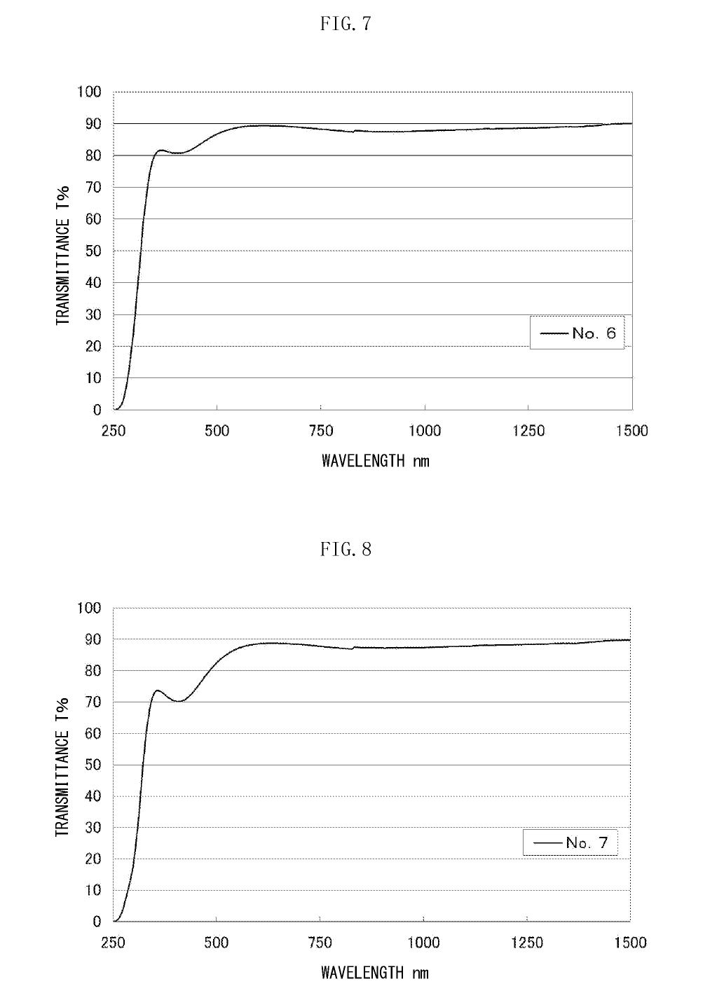

FIG. 7 shows a transmittance curve of Sample No. 6 with a thickness of 1.8 mm at a wavelength of 1,100 nm.

FIG. 8 shows a transmittance curve of Sample No. 7 with a thickness of 1.8 mm at a wavelength of 1,100 nm.

The solar transmittance and the visible light transmittance refer to values measured in conformity of JIS R 3106 at a thickness of 3.2 mm. Note that an illuminant c was used as a light source for the measurement of the visible light transmittance

As evident from the tables, each of Sample Nos. 2 to 11 and 13 to 27 has a strain point of 520° C. to 700° C., thus having high heat resistance. Further, each of Sample Nos. 2 to 11 and 13 to 27 has a thermal expansion coefficient of 70×10⁻⁷ to 100×10⁻⁷/° C., and hence the thermal expansion coefficient is easily matched with those of constituent members such as a PDP. In addition, in each of Sample Nos. 2 to 11 and 13 to 27, the total iron content (t-Fe) was less than 0.04%, the value of Fe²⁺/t-Fe₂O₃ was 0.76 or less, the value of nd was 1.50 to 1.65, and the transmittance of each sample with a thickness of 1.8 mm at a wavelength 1,100 nm was 86 to 92%. Note that Sample No. 2 had a relatively much residual SO₃ amount and included many bubbles.

Each of Sample Nos. 7 and 8 is glass obtained by further reducing Sample No. 6. Although the value of Fe²⁺/t-Fe in glass was not measured, it is estimated from the transmittance curves shown in the figures that the value of Fe²⁺/t-Fe is more than 0.76. This shows that the color of the glass changed to a brown color, resulting in the decrease of the transmittance.

Meanwhile, Sample No. 1 is the high strain point glass disclosed in Patent Literature 4. When the high strain point glass is used in a CIGS-based solar cell, iron in the glass sheet may diffuse in a photoelectric conversion film, resulting in the deterioration of the conversion efficiency. On the other hand, when this high strain point glass is used in a super straight type solar cell typified by a CdTe-based solar cell, glass coloration due to Fe²⁺ may deteriorate the conversion efficiency. Further, when the high strain point glass is used in a display, glass coloration due to Fe²⁺ deteriorates the transmittance, and hence it is believed that the high strain point glass cannot contribute to reducing the power consumption of the display. Meanwhile, Sample No. 12 is the high transmittance glass disclosed in Patent Literature 3. This glass has a high transmittance but has a low strain point, and hence the glass is not suitable for applications of a display or a thin-film solar cell, each of which requires high heat resistance.

### INDUSTRIAL APPLICABILITY

The glass of the present invention can also be applied to a silicon solar cell in addition to an FPD such as a PDP and a field emission display, a thin-film solar cell such as a CIS-based solar cell and a CdTe-based solar cell, and a dye-sensitized solar cell.

1. A glass, comprising, as a glass composition, in mass % in terms of the following oxides, 40 to 65% of SiO₂, 2 to 20% of Al₂O₃, 0 to 20% of B₂O₃, 0 to 15% of MgO, 0 to 15% of CaO, 0 to 20% of SrO, 0 to 20% of BaO, 0 to 10% of Li₂O, 0.1 to 20% of Na₂O, 0.1 to 20% of K₂O, 0 to 10% of ZrO₂, 0 to less than 0.04% of Fe₂O₃, and 0 to 0.5% of SO₃, wherein a transmittance of the glass with a thickness of 1.8 mm at a wavelength 1,100 nm is 86 to 92%.

2. The glass according to claim 1, wherein a mass ratio of Fe²⁺ in terms of FeO with respect to a total iron content (t-Fe) in terms of Fe₂O₃, that is, Fe²⁺/t-Fe is 0.70 or less.

3. The glass according to claim 1, wherein the glass comprises, in mass % in terms of the following oxides, 0.005 to 0.1% of SO₃ and 0.001 to 0.035% of Fe₂O₃.

4. The glass according to claim 1, wherein the glass has a strain point of 520 to 700° C.

5. The glass according to claim 1, wherein the glass has a thermal expansion coefficient at 30 to 380° C. of 70×10⁻⁷ to 100×10⁻⁷/° C.

6. The glass according to claim 1, wherein the glass has a sheet shape and has at least one of an anti-reflective film and a transparent conductive film formed on a surface thereof.

7. The glass according to claim 1, wherein the glass is used in a display.

8. The glass according to claim 1, wherein the glass is used in a solar cell.

9. The glass according to claim 2, wherein the glass comprises, in mass % in terms of the following oxides, 0.005 to 0.1% of SO₃ and 0.001 to 0.035% of Fe₂O₃.

10. The glass according to claim 2, wherein the glass has a strain point of 520 to 700° C.

11. The glass according to claim 2, wherein the glass has a thermal expansion coefficient at 30 to 380° C. of 70×10⁻⁷ to 100×10⁻⁷/° C.

12. The glass according to claim 2, wherein the glass has a sheet shape and has at least one of an anti-reflective film and a transparent conductive film formed on a surface thereof.

13. The glass according to claim 2, wherein the glass is used in a display.

14. The glass according to claim 2, wherein the glass is used in a solar cell.
